(19) United States
(12) Patent Application Publication
(10) Pub. No.: US 2024/0373550 A1
(43) Pub. Date: Nov. 7, 2024

(54) WIRING BOARD, MANUFACTURING METHOD OF SAME, FILM, AND LAMINATE

(71) Applicant: FUJIFILM Corporation, Tokyo (JP)

(72) Inventor: Yasuyuki SASADA, Kanagawa (JP)

(73) Assignee: FUJIFILM Corporation, Tokyo (JP)

(21) Appl. No.: 18/779,090

(22) Filed: Jul. 22, 2024

Related U.S. Application Data
(63) Continuation of application No. PCT/JP2023/002310, filed on Jan. 25, 2023.

(30) Foreign Application Priority Data
Jan. 31, 2022 (JP) 2022-013504

(51) Int. Cl. H05K 1/03; H05K 1/02; H05K 3/06

(52) U.S. Cl. CPC H05K 1/036; H05K 1/024; H05K 3/06; H05K 2201/0141; H05K 2201/015; H05K 2201/0195; H05K 2201/0317

(57) ABSTRACT

A wiring board including a first resin layer, wiring patterns arranged on at least one surface of the first resin layer, and a second resin layer disposed between the wiring patterns and on the wiring patterns, in which, in a cross section along a thickness direction, an interface roughness Rz1 of an interface between the first resin layer and the second resin layer is larger than an interface roughness Rz2 of an interface between the first resin layer and the wiring pattern; and applications thereof are provided.

### CROSS-REFERENCE TO RELATED APPLICATIONS

This application is a continuation application of International Application No. PCT/JP2023/002310, filed Jan. 25, 2023, the disclosure of which is incorporated herein by reference in its entirety. Further, this application claims priority from Japanese Patent Application No. 2022-013504, filed Jan. 31, 2022, the disclosure of which is incorporated herein by reference in its entirety.

### BACKGROUND OF THE INVENTION

### 1. Field of the Invention

The present disclosure relates to a wiring board, a manufacturing method of the same, a film, and a laminate.

### 2. Description of the Related Art

In recent years, frequencies used in communication equipment tend to be extremely high. In order to suppress transmission loss in a high frequency band, insulating materials used in a circuit board are required to have a lowered relative permittivity and a lowered dielectric loss tangent.

In the related art, polyimide is commonly used as the insulating material used in the circuit board, a liquid crystal polymer which has high heat resistance and low water absorption and is small in transmission loss in the high frequency band has been attracted.

For example, WO2020/090688A discloses a metal-clad laminated plate including an insulating layer containing a liquid crystal polymer and a metal foil overlapping the insulating layer, in which an average length (RSm) of a contour curve element, which is calculated from a roughness curve obtained from a cross section of the metal-clad laminated plate at a surface of the metal foil overlapping the insulating layer, is 10 μm or more and 65 μm or less, a plate thickness accuracy of the metal-clad laminated plate is less than ±20%, and a peel strength of the metal foil from the insulating layer is 0.8 N/mm or more.

### SUMMARY OF THE INVENTION

According to one embodiment of the present invention, there are provided a wiring board having excellent adhesiveness, a manufacturing method of the same, and a laminate.

An object to be achieved by another embodiment of the present invention is to provide a film having excellent adhesiveness with a metal.

The methods for achieving the above-described objects include the following aspects.
<1>

A wiring board, comprising:
a first resin layer;
wiring patterns arranged on at least one surface of the first resin layer; and
a second resin layer disposed between the wiring patterns and on the wiring patterns,
in which, in a cross section along a thickness direction, an interface roughness Rz1 of an interface between the first resin layer and the second resin layer is larger than an interface roughness Rz2 of an interface between the first resin layer and the wiring pattern.
<2>

The wiring board according to <1>,
in which the interface roughness Rz2 is less than 1.0 μm.
<3>

The wiring board according to <1> or <2>,
in which the interface roughness Rz1 is 1.0 μm or more.
<4>

The wiring board according to any one of <1> to <3>,
in which an elastic modulus of the second resin layer between the wiring patterns at 160° C. is less than 1.0 GPa.
<5>

The wiring board according to any one of <1> to <4>,
in which a thickness of the wiring pattern is 2 μm to 30 μm. <6>

The wiring board according to any one of <1> to <5>, in which a dielectric loss tangent of the first resin layer is 0.01 or less.
<7>

The wiring board according to any one of <1> to <6>,
in which the first resin layer comprises at least one polymer selected from the group consisting of a liquid crystal polymer, a fluororesin, a polymerized substance of a compound which has a cyclic aliphatic hydrocarbon group and a group having an ethylenically unsaturated bond, a polyphenylene ether, and an aromatic polyether ketone.
<8>

The wiring board according to any one of <1> to <7>,
in which an elastic modulus of the first resin layer at 160° C. is 0.5 GPa or more.
<9>

A film comprising:
alkali-soluble particles or acid-soluble particles,
in which a dielectric loss tangent is 0.01 or less.
<10>

A film, comprising:
alkali-soluble particles or acid-soluble particles; and
at least one polymer selected from the group consisting of a liquid crystal polymer, a fluororesin, a polymerized substance of a compound which has a cyclic aliphatic hydrocarbon group and a group having an ethylenically unsaturated bond, a polyphenylene ether, and an aromatic polyether ketone.
<11>

A film, comprising:
a layer A; and
a layer B provided on at least one surface of the layer A,
in which a dielectric loss tangent of the layer A is 0.01 or less, and
the layer B comprises alkali-soluble particles or acid-soluble particles, and at least one polymer selected from the group consisting of a liquid crystal polymer, a fluororesin, a polymerized substance of a compound which has a cyclic aliphatic hydrocarbon group and a group having an ethylenically unsaturated bond, a polyphenylene ether, and an aromatic polyether ketone.
<12>

A laminate, comprising:
the film according to <9> or <10>; and
a metal layer which is disposed on at least one surface of the film and has a surface roughness of 1.0 μm or less.
<13>

A laminate, comprising:
the film according to <11>; and
a metal layer which is disposed on the layer B of the film and has a surface roughness of 1.0 μm or less.
<14>

A manufacturing method of a wiring board, comprising:
etching the metal layer in the laminate according to <12> or <13> to produce a substrate with a wiring pattern, including a first resin substrate and a wiring pattern disposed on at least one surface of the first resin substrate;
superimposing a second resin substrate on the wiring pattern of the substrate with a wiring pattern; and
heating the substrate with a wiring pattern and the second resin substrate in a state of being superimposed on each other to obtain a wiring board,
in which, in a cross section along a thickness direction, an interface roughness Rz1 of an interface between the first resin substrate and the second resin substrate is larger than an interface roughness Rz2 of an interface between the first resin substrate and the wiring pattern.

According to one embodiment of the present invention, there are provided a wiring board having excellent adhesiveness, a manufacturing method of the same, and a laminate.

According to another embodiment of the present invention, there is provided a film having excellent adhesiveness with a metal.

### DESCRIPTION OF THE PREFERRED EMBODIMENTS

Hereinafter, the contents of the present disclosure will be described in detail. The description of configuration requirements below is made based on representative embodiments of the present disclosure in some cases, but the present disclosure is not limited to such embodiments.

In the present specification, a numerical range shown using “to” indicates a range including numerical values described before and after “to” as a lower limit value and an upper limit value.

In a numerical range described in a stepwise manner in the present disclosure, an upper limit value or a lower limit value described in one numerical range may be replaced with an upper limit or a lower limit in another numerical range described in a stepwise manner. In addition, in a numerical range described in the present disclosure, an upper limit value or a lower limit value described in the numerical range may be replaced with a value described in an example.

In addition, in a case where substitution or unsubstitution is not noted in regard to the notation of a “group” (atomic group) in the present specification, the “group” includes not only a group that does not have a substituent but also a group having a substituent. For example, the concept of an “alkyl group” includes not only an alkyl group that does not have a substituent (unsubstituted alkyl group) but also an alkyl group having a substituent (substituted alkyl group).

Furthermore, in the present disclosure, a combination of two or more preferred embodiments is a more preferred embodiment.

In addition, the weight-average molecular weight (Mw) and the number-average molecular weight (Mn) in the present disclosure are molecular weights converted using polystyrene as a standard substance by performing detection with a gel permeation chromatography (GPC) analysis apparatus using TSKgel SuperHM-H (trade name, manufactured by Tosoh Corporation) column, a solvent of pentafluorophenol (PFP) and chloroform at a mass ratio of 1:2, and a differential refractometer, unless otherwise specified.

### Wiring Board

The wiring board according to the present disclosure includes a first resin layer, wiring patterns arranged on at least one surface of the first resin layer, and a second resin layer disposed between the wiring patterns and on the wiring patterns, in which, in a cross section along a thickness direction, an interface roughness Rz1 of an interface between the first resin layer and the second resin layer is larger than an interface roughness Rz2 of an interface between the first resin layer and the wiring pattern.

As a result of intensive studies, the present inventor has found that a wiring board having excellent adhesiveness can be obtained by adopting the above-described configuration.

The detailed mechanism for obtaining the above-described effects is not clear, but assumed as follows.

It is considered that, in the wiring board according to the present disclosure, since the interface roughness Rz1 of the interface between the first resin layer and the second resin layer is larger than the interface roughness Rz2 of the interface between the first resin layer and the wiring pattern in the cross section along the thickness direction, adhesiveness between the first resin layer and the second resin layer is relatively enhanced in a plane direction.

On the other hand, in WO2020/090688A, the interface roughness of the interface between the first resin layer and the second resin layer and the interface roughness of the interface between the first resin layer and the wiring pattern are not focused on.

### <First Resin Layer>

The wiring board according to the present disclosure includes a first resin layer. The first resin layer contains a resin (that is, a polymer). The type of the polymer contained in the first resin layer is not particularly limited, but a dielectric loss tangent thereof is preferably 0.01 or less, more preferably 0.005 or less, and still more preferably 0.003 or less. The lower limit value of the dielectric loss tangent is not particularly limited, but is, for example, more than 0.

The dielectric loss tangent is measured by a resonance perturbation method at a frequency of 10 GHz. A 10 GHz cavity resonator (CP531 manufactured by Kanto Electronics Application & Development Inc.) is connected to a network analyzer (“E8363B” manufactured by Agilent Technology), and a sample (width: 2 mm×length: 80 mm) is inserted into the cavity resonator, and the dielectric loss tangent of the sample is measured based on a change in resonance frequency for 96 hours before and after the insertion in an environment of a temperature of 25° C. and a humidity of 60% RH.

From the viewpoint of reducing the dielectric loss tangent, the first resin layer preferably contains a polymer having a dielectric loss tangent of 0.01 or less. The dielectric loss tangent of the polymer is preferably 0.004 or less, more preferably 0.0035 or less, and particularly preferably 0.003 or less. The lower limit value of the dielectric loss tangent of the polymer is not particularly limited, but is, for example, more than 0.

In the present disclosure, the measurement of the dielectric loss tangent of the polymer is carried out according to the above-described method of measuring a dielectric loss tangent by identifying or isolating a chemical structure of the polymer and using a powdered sample of the polymer to be measured.

The first resin layer may contain only one kind of the polymer, or two or more kinds of the polymers.

Examples of the polymer contained in the first resin layer include thermoplastic resins such as a liquid crystal polymer, a fluorine-based resin, a polymerized substance of a compound which has a cyclic aliphatic hydrocarbon group and a group having an ethylenically unsaturated bond, polyether ether ketone, polyolefin, polyamide, polyester, polyphenylene sulfide, polyether ketone, polycarbonate, polyethersulfone, polyphenylene ether and a modified product thereof, and polyetherimide; elastomers such as a copolymer of glycidyl methacrylate and polyethylene; and thermosetting resins such as a phenol resin, an epoxy resin, a polyimide resin, and a cyanate resin.

Among these, from the viewpoint of further reducing the dielectric loss tangent, the first resin layer preferably contains at least one polymer selected from the group consisting of a liquid crystal polymer, a fluororesin, a polymerized substance of a compound which has a cyclic aliphatic hydrocarbon group and a group having an ethylenically unsaturated bond, polyphenylene ether, and aromatic polyether ketone; and more preferably contains at least one polymer selected from the group consisting of a liquid crystal polymer, a fluororesin, and a polymerized substance of a compound which has a cyclic aliphatic hydrocarbon group and a group having an ethylenically unsaturated bond.

### —Liquid Crystal Polymer—

In the present disclosure, the type of the liquid crystal polymer is not particularly limited, and a known liquid crystal polymer can be used.

In addition, the liquid crystal polymer may be a thermotropic liquid crystal polymer which exhibits liquid crystallinity in a molten state, or may be a lyotropic liquid crystal polymer which exhibits liquid crystallinity in a solution state. In addition, in a case where the liquid crystal polymer is a thermotropic liquid crystal polymer, the liquid crystal polymer is preferably a liquid crystal polymer which is molten at a temperature of 450° C. or lower.

Examples of the liquid crystal polymer include a liquid crystal polyester, a liquid crystal polyester amide in which an amide bond is introduced into the liquid crystal polyester, a liquid crystal polyester ether in which an ether bond is introduced into the liquid crystal polyester, and a liquid crystal polyester carbonate in which a carbonate bond is introduced into the liquid crystal polyester.

In addition, as the liquid crystal polymer, from the viewpoint of liquid crystallinity, a polymer having an aromatic ring is preferable, and an aromatic polyester or an aromatic polyester amide is more preferable.

Furthermore, the liquid crystal polymer may be a polymer in which an imide bond, a carbodiimide bond, a bond derived from an isocyanate, such as an isocyanurate bond, or the like is further introduced into the aromatic polyester or the aromatic polyester amide.

In addition, it is preferable that the liquid crystal polymer is a wholly aromatic liquid crystal polymer formed of only an aromatic compound as a raw material monomer.

Examples of the liquid crystal polymer include the following liquid crystal polymers.
1) a liquid crystal polymer obtained by polycondensing (i) an aromatic hydroxycarboxylic acid, (ii) an aromatic dicarboxylic acid, and (iii) at least one compound selected from the group consisting of an aromatic diol, an aromatic hydroxyamine, and an aromatic diamine;
2) a liquid crystal polymer obtained by polycondensing a plurality of types of aromatic hydroxycarboxylic acids;
3) a liquid crystal polymer obtained by polycondensing (i) an aromatic dicarboxylic acid and (ii) at least one compound selected from the group consisting of an aromatic diol, an aromatic hydroxyamine, and an aromatic diamine;
4) a liquid crystal polymer obtained by polycondensing (i) polyester such as polyethylene terephthalate and (ii) an aromatic hydroxycarboxylic acid.

Here, the aromatic hydroxycarboxylic acid, the aromatic dicarboxylic acid, the aromatic diol, the aromatic hydroxyamine, and the aromatic diamine may be each independently replaced with a polycondensable derivative.

For example, the aromatic hydroxycarboxylic acid and the aromatic dicarboxylic acid can be replaced with aromatic hydroxycarboxylic acid ester and aromatic dicarboxylic acid ester, by converting a carboxy group into an alkoxycarbonyl group or an aryloxycarbonyl group.

The aromatic hydroxycarboxylic acid and the aromatic dicarboxylic acid can be replaced with aromatic hydroxycarboxylic acid halide and aromatic dicarboxylic acid halide, by converting a carboxy group into a haloformyl group.

The aromatic hydroxycarboxylic acid and the aromatic dicarboxylic acid can be replaced with aromatic hydroxycarboxylic acid anhydride and aromatic dicarboxylic acid anhydride, by converting a carboxy group into an acyloxycarbonyl group.

Examples of a polymerizable derivative of a compound having a hydroxy group, such as an aromatic hydroxycarboxylic acid, an aromatic diol, and an aromatic hydroxyamine, include a derivative (acylated product) obtained by acylating a hydroxy group and converting the acylated group into an acyloxy group.

For example, the aromatic hydroxycarboxylic acid, the aromatic diol, and the aromatic hydroxyamine can be each replaced with an acylated product by acylating a hydroxy group and converting the acylated group into an acyloxy group.

Examples of a polymerizable derivative of a compound having an amino group, such as an aromatic hydroxyamine or an aromatic diamine, include a derivative (acylated product) obtained by acylating an amino group and converting the acylated group to an acylamino group.

For example, the aromatic hydroxyamine and the aromatic diamine can be each replaced with an acylated product by acylating an amino group and converting the acylated group into an acylamino group.

From the viewpoint of liquid crystallinity, the liquid crystal polymer preferably has a constitutional unit represented by any of Formulae 1 to 3, more preferably has a constitutional unit represented by Formula 1, and particularly preferably has a constitutional unit represented by Formula 1, a constitutional unit represented by Formula 2, and a constitutional unit represented by Formula 3. Hereinafter, the constitutional unit represented by Formula 1 and the like are also referred to as “unit 1” and the like.

—O—Ar¹—CO— Formula 1

—CO—Ar²—CO Formula 2

—X—Ar³—Y Formula 3

In Formulae 1 to 3, Ar¹ represents a phenylene group, a naphthylene group, or a biphenylylene group, Ar² and Ar³ each independently represent a phenylene group, a naphthylene group, a biphenylylene group, or a group represented by Formula 4, X and Y each independently represent an oxygen atom or an imino group, and hydrogen atoms in Ar¹ to Ar³ may be each independently substituted with a halogen atom, an alkyl group, or an aryl group.

—Ar⁴—Z—Ar⁵— Formula 4

In Formula 4, Ar⁴ and Ar⁵ each independently represent a phenylene group or a naphthylene group, and Z represents an oxygen atom, a sulfur atom, a carbonyl group, a sulfonyl group, or an alkylene group.

Examples of the above-described halogen atom include a fluorine atom, a chlorine atom, a bromine atom, and an iodine atom.

Examples of the alkyl group include a methyl group, an ethyl group, an n-propyl group, an isopropyl group, an n-butyl group, an isobutyl group, an s-butyl group, a t-butyl group, an n-hexyl group, a 2-ethylhexyl group, an n-octyl group, and an n-decyl group. The number of carbon atoms in the alkyl group is preferably 1 to 10.

Examples of the aryl group include a phenyl group, an o-tolyl group, an m-tolyl group, a p-tolyl group, a 1-naphthyl group, and a 2-naphthyl group. The number of carbon atoms in the aryl group is preferably 6 to 20.

In a case where the hydrogen atom in Ar¹ to Ar³ is substituted with a halogen atom, an alkyl group, or an aryl group, the number of each of substituents in Ar¹, Ar², and Ar³ independently is preferably 2 or less and more preferably 1.

Examples of the alkylene group include a methylene group, a 1,1-ethanediyl group, a 1-methyl-1,1-ethanediyl group, a 1,1-butanediyl group, and a 2-ethyl-1,1-hexanediyl group. The number of carbon atoms in the alkylene group is preferably 1 to 10.

The unit 1 can be introduced, for example, using aromatic hydroxycarboxylic acid as a raw material.

The unit 2 can be introduced, for example, using aromatic dicarboxylic acid as a raw material.

The unit 3 can be introduced, for example, using aromatic hydroxylamine as a raw material.

Here, the aromatic hydroxycarboxylic acid, the aromatic dicarboxylic acid, the aromatic diol, and the aromatic hydroxylamine may be each independently replaced with a polycondensable derivative.

For example, the aromatic hydroxycarboxylic acid and the aromatic dicarboxylic acid can be replaced with aromatic hydroxycarboxylic acid ester and aromatic dicarboxylic acid ester, by converting a carboxy group into an alkoxycarbonyl group or an aryloxycarbonyl group.

The aromatic hydroxycarboxylic acid and the aromatic dicarboxylic acid can be replaced with aromatic hydroxycarboxylic acid halide and aromatic dicarboxylic acid halide, by converting a carboxy group into a haloformyl group.

The aromatic hydroxycarboxylic acid and the aromatic dicarboxylic acid can be replaced with aromatic hydroxycarboxylic acid anhydride and aromatic dicarboxylic acid anhydride, by converting a carboxy group into an acyloxycarbonyl group.

Examples of a polymerizable derivative of a compound having a hydroxy group, such as an aromatic hydroxycarboxylic acid and an aromatic hydroxyamine, include a derivative (acylated product) obtained by acylating a hydroxy group and converting the acylated group into an acyloxy group.

For example, the aromatic hydroxycarboxylic acid and the aromatic hydroxylamine can be each replaced with an acylated product by acylating a hydroxy group and converting the acylated group into an acyloxy group.

Examples of a polycondensable derivative of the aromatic hydroxylamine include a substance (acylated product) obtained by acylating an amino group to convert the amino group into an acylamino group.

For example, the aromatic hydroxyamine can be replaced with an acylated product by acylating an amino group and converting the acylated group into an acylamino group.

In Formula 1, Ar¹ is preferably a p-phenylene group, a 2,6-naphthylene group, or a 4,4′-biphenylylene group, and more preferably a 2,6-naphthylene group.

In a case where Ar¹ is a p-phenylene group, the unit 1 is, for example, a constitutional unit derived from p-hydroxybenzoic acid.

In a case where Ar¹ is a 2,6-naphthylene group, the unit 1 is, for example, a constitutional unit derived from 6-hydroxy-2-naphthoic acid.

In a case where Ar is a 4,4′-biphenylylene group, the unit 1 is, for example, a constitutional unit derived from 4′-hydroxy-4-biphenylcarboxylic acid.

In Formula 2, Ar² is preferably a p-phenylene group, an m-phenylene group, or a 2,6-naphthylene group, and more preferably an m-phenylene group.

In a case where Ar² is a p-phenylene group, the unit 2 is, for example, a constitutional unit derived from terephthalic acid.

In a case where Ar² is an m-phenylene group, the unit 2 is, for example, a constitutional unit derived from isophthalic acid.

In a case where Ar² is a 2,6-naphthylene group, the unit 2 is, for example, a constitutional unit derived from 2,6-naphthalenedicarboxylic acid.

In Formula 3, Ar³ is preferably a p-phenylene group or a 4,4′-biphenylylene group, and more preferably a p-phenylene group.

In a case where Ar³ is a p-phenylene group, the unit 2 is, for example, a constitutional unit derived from p-aminophenol.

In a case where Ar³ is a 4,4′-biphenylylene group, the unit 2 is, for example, a constitutional unit derived from 4-amino-4′-hydroxybiphenyl.

With respect to the total content of the unit 1, the unit 2, and the unit 3, a content of the unit 1 is preferably 30 mol % or more, a content of the unit 2 is preferably 35% or less, and a content of the unit 3 is preferably 35 mol % or less.

The content of the unit 1 is preferably 30 mol % to 80 mol %, more preferably 30 mol % to 60 mol %, and particularly preferably 30 mol % to 40 mol % with respect to the total content of the unit 1, the unit 2, and the unit 3.

The content of the unit 2 is preferably 10 mol % to 35 mol %, more preferably 20 mol % to 35 mol %, and particularly preferably 30 mol % to 35 mol % with respect to the total content of the unit 1, the unit 2, and the unit 3.

The content of the unit 3 is preferably 10 mol % to 35 mol %, more preferably 20 mol % to 35 mol %, and particularly preferably 30 mol % to 35 mol % with respect to the total content of the unit 1, the unit 2, and the unit 3.

The total content of the constitutional units is a value obtained by totaling a substance amount (mol) of each constitutional unit. The substance amount of each constitutional unit is calculated by dividing a mass of each constitutional unit constituting the liquid crystal polymer by a formula weight of each constitutional unit.

In a case where a ratio of the content of the unit 2 to the content of the unit 3 is expressed as [Content of unit 2]/[Content of unit 3] (mol/mol), the ratio is preferably 0.9/1 to 1/0.9, more preferably 0.95/1 to 1/0.95, and still more preferably 0.98/1 to 1/0.98.

The liquid crystal polymer may have two kinds or more of each of the unit 1 to the unit 3 independently. In addition, the liquid crystal polymer may have a constitutional unit other than the unit 1 to the unit 3. A content of other constitutional units is preferably 10% by mole or less and more preferably 5% by mole or less with respect to the total amount of all constitutional units.

Since the solubility in a solvent is excellent, the liquid crystal polymer preferably has a unit 3 in which at least one of X or Y is an imino group, that is, preferably has at least one of a constitutional unit derived from an aromatic hydroxylamine or a constitutional unit derived from an aromatic diamine, and it is more preferable to have only a unit 3 in which at least one of X or Y is an imino group.

It is preferable that the liquid crystal polymer is produced by melt-polymerizing raw material monomers corresponding to the constitutional units constituting the liquid crystal polymer. The melt polymerization may be carried out in the presence of a catalyst. Examples of the catalyst include metal compounds such as magnesium acetate, stannous acetate, tetrabutyl titanate, lead acetate, sodium acetate, potassium acetate, and antimony trioxide, and nitrogen-containing heterocyclic compounds such as 4-(dimethylamino)pyridine and 1-methylimidazole. The catalyst is preferably a nitrogen-containing heterocyclic compound. The melt polymerization may be further carried out by solid phase polymerization as necessary.

A flow start temperature of the liquid crystal polymer is preferably 180° C. or higher, more preferably 200° C. or higher, and still more preferably 250° C. or higher. In addition, the flow start temperature thereof is preferably 350° C. or lower, more preferably 330° C. or lower, and still more preferably 310° C. or lower. In a case where the flow start temperature of the liquid crystal polymer is within the above-described range, the solubility, the heat resistance, the strength, and the rigidity are excellent, and the viscosity of the solution is appropriate.

The flow start temperature, also referred to as a flow temperature, is a temperature at which a viscosity of 4,800 Pa·s (48,000 poises) is exhibited in a case where the liquid crystal polymer is melted and extruded from a nozzle having an inner diameter of 1 mm and a length of 10 mm while the temperature is raised at a rate of 4° C./min under a load of 9.8 MPa (100 kg/cm2) using a capillary rheometer and is a guideline for the molecular weight of the liquid crystal polymer (sec p. 95 of “Liquid Crystal Polymers—Synthesis/Molding/Applications—”, written by Naoyuki Koide, CMC Corporation, Jun. 5, 1987).

In addition, a weight-average molecular weight of the liquid crystal polymer is preferably 1,000,000 or less, more preferably 3,000 to 300,000, still more preferably 5,000 to 100,000, and particularly preferably 5,000 to 30,000. In a case where the weight-average molecular weight of the liquid crystal polymer is within the above-described range, a film after heat treatment is excellent in thermal conductivity, heat resistance, strength, and rigidity in the thickness direction.

### —Fluororesin—

In the present disclosure, the type of the fluororesin is not particularly limited, and a known fluororesin can be used.

Examples of the fluororesin include a homopolymer and a copolymer containing a constitutional unit derived from a fluorinated α-olefin monomer, that is, an α-olefin monomer containing at least one fluorine atom. In addition, examples of the fluororesin include a copolymer containing a constitutional unit derived from a fluorinated α-olefin monomer, and a constitutional unit derived from a non-fluorinated ethylenically unsaturated monomer reactive to the fluorinated α-olefin monomer.

Examples of the fluorinated α-olefin monomer include CF₂═CF₂, CHF—CF₂, CH₂═CF₂, CHCl═CHF, CClF═CF₂, CCl₂═CF₂, CClF═CClF, CHF═CCl₂, CH₂═CClF, CCl₂═CClF, CF₃CF═CF₂, CF₃CF═CHF, CF₃CH═CF₂, CF₃CH═CH₂, CHF₂CH═CHF, CF₃CF═CF₂, and perfluoro(alkyl having 2 to 8 carbon atoms) vinyl ether (for example, perfluoromethyl vinyl ether, perfluoropropyl vinyl ether, and perfluorooctyl vinyl ether). Among these, as the fluorinated α-olefin monomer, at least one monomer selected from the group consisting of tetrafluoroethylene (CF₂═CF₂), chlorotrifluoroethylene (CClF═CF₂), (perfluorobutyl)ethylene, vinylidene fluoride (CH₂═CF₂), and hexafluoropropylene (CF₂═CFCF₃) is preferable.

Examples of the non-fluorinated ethylenically unsaturated monomer include ethylene, propylene, butene, and an ethylenically unsaturated aromatic monomer (for example, styrene and α-methylstyrene).

The fluorinated α-olefin monomer may be used alone or in combination of two or more thereof.

In addition, the non-fluorinated ethylenically unsaturated monomer may be used alone or in combination of two or more thereof.

Examples of the fluororesin include polychlorotrifluoroethylene (PCTFE), poly(chlorotrifluoroethylene-propylene), poly(ethylene-tetrafluoroethylene) (ETFE), poly(ethylene-chlorotrifluoroethylene) (ECTFE), poly(hexafluoropropylene), poly(tetrafluoroethylene) (PTFE), poly(tetrafluoroethylene-ethylene-propylene), poly(tetrafluoroethylene-hexafluoropropylene) (FEP), poly(tetrafluoroethylene-propylene) (FEPM), poly(tetrafluoroethylene-perfluoropropylene vinyl ether), poly(tetrafluoroethylene-perfluoroalkyl vinyl ether) (PFA) (for example, poly(tetrafluoroethylene-perfluoropropyl vinyl ether)), polyvinyl fluoride (PVF), polyvinylidene fluoride (PVDF), poly(vinylidene fluoride-chlorotrifluoroethylene), perfluoropolyether, perfluorosulfonic acid, and perfluoropolyoxetane.

The fluororesin may have a constitutional unit derived from fluorinated ethylene or fluorinated propylene.

The fluororesin may be used alone or in combination of two or more thereof.

The fluororesin is preferably FEP, PFA, ETFE, or PTFE.

The FEP is available from Du Pont as the trade name of TEFLON (registered trademark) FEP or from DAIKIN INDUSTRIES, LTD. as the trade name of NEOFLON FEP. The PFA is available from DAIKIN INDUSTRIES, LTD. as the trade name of NEOFLON PFA, from Du Pont as the trade name of TEFLON (registered trademark) PFA, or from Solvay Solexis as the trade name of HYFLON PFA.

The fluororesin more preferably includes PTFE. The PTFE may be a PTFE homopolymer, a partially modified PTFE homopolymer, or a combination including one or both of these. The partially modified PTFE homopolymer preferably contains a constitutional unit derived from a comonomer other than tetrafluoroethylene in an amount of less than 1% by mass based on the total mass of the polymer.

The fluororesin may be a crosslinkable fluoropolymer having a crosslinkable group. The crosslinkable fluoropolymer can be crosslinked by a known crosslinking method in the related art. One of the representative crosslinkable fluoropolymers is a fluoropolymer having (meth)acryloyloxy. For example, the crosslinkable fluoropolymer can be represented by Formula: H₂C═CR′COO—(CH₂)ₙ—R—(CH₂)ₙ—OOCR′═CH₂.

In the formula, R is an oligomer chain having a constitutional unit derived from the fluorinated α-olefin monomer, R′ is H or —CH₃, and n is 1 to 4. R may be a fluorine-based oligomer chain having a constitutional unit derived from tetrafluoroethylene.

In order to initiate a radical crosslinking reaction through the (meth)acryloyloxy group in the fluororesin, by exposing the fluoropolymer having a (meth)acryloyloxy group to a free radical source, a crosslinked fluoropolymer network can be formed. The free radical source is not particularly limited, and suitable examples thereof include a photoradical polymerization initiator and an organic peroxide. Appropriate photoradical polymerization initiators and organic peroxides are well known in the art. The crosslinkable fluoropolymer is commercially available, and examples thereof include Viton B manufactured by Du Pont.

### Polymerized Substance of Compound Which Has Cyclic Aliphatic Hydrocarbon Group and Group Having Ethylenically Unsaturated Bond—

Examples of the polymerized substance of a compound which has a cyclic aliphatic hydrocarbon group and a group having an ethylenically unsaturated bond include thermoplastic resins having a constitutional unit derived from a cyclic olefin monomer such as norbornene and a polycyclic norbornene-based monomer.

The polymerized substance of a compound which has a cyclic aliphatic hydrocarbon group and a group having an ethylenically unsaturated bond may be a ring-opened polymer of the above-described cyclic olefin, a hydrogenated product of a ring-opened copolymer using two or more cyclic olefins, or an addition polymer of a cyclic olefin and a linear olefin or aromatic compound having an ethylenically unsaturated bond such as a vinyl group. In addition, a polar group may be introduced into the polymerized substance of a compound which has a cyclic aliphatic hydrocarbon group and a group having an ethylenically unsaturated bond.

The polymerized substance of a compound which has a cyclic aliphatic hydrocarbon group and a group having an ethylenically unsaturated bond may be used alone or in combination of two or more thereof.

A ring structure of the cyclic aliphatic hydrocarbon group may be a single ring, a fused ring in which two or more rings are fused, or a crosslinked ring.

Examples of the ring structure of the cyclic aliphatic hydrocarbon group include a cyclopentane ring, a cyclohexane ring, a cyclooctane ring, an isophorone ring, a norbornane ring, and a dicyclopentane ring.

The compound which has a cyclic aliphatic hydrocarbon group and a group having an ethylenically unsaturated bond is not particularly limited, and examples thereof include a (meth)acrylate compound having a cyclic aliphatic hydrocarbon group, a (meth)acrylamide compound having a cyclic aliphatic hydrocarbon group, and a vinyl compound having a cyclic aliphatic hydrocarbon group. Among these, preferred examples thereof include a (meth)acrylate compound having a cyclic aliphatic hydrocarbon group. In addition, the compound which has a cyclic aliphatic hydrocarbon group and a group having an ethylenically unsaturated bond may be a monofunctional ethylenically unsaturated compound or a polyfunctional ethylenically unsaturated compound.

The number of cyclic aliphatic hydrocarbon groups in the compound which has a cyclic aliphatic hydrocarbon group and a group having an ethylenically unsaturated bond may be 1 or more, and may be 2 or more.

It is sufficient that the polymerized substance of a compound which has a cyclic aliphatic hydrocarbon group and a group having an ethylenically unsaturated bond is a polymer obtained by polymerizing at least one compound which has a cyclic aliphatic hydrocarbon group and a group having an ethylenically unsaturated bond, and it may be a polymerized substance of two or more kinds of the compound which has a cyclic aliphatic hydrocarbon group and a group having an ethylenically unsaturated bond or a copolymer with other ethylenically unsaturated compounds having no cyclic aliphatic hydrocarbon group.

In addition, the polymerized substance of a compound which has a cyclic aliphatic hydrocarbon group and a group having an ethylenically unsaturated bond is preferably a cycloolefin polymer.

### —Polyphenylene Ether—

In the polyphenylene ether, from the viewpoint of dielectric loss tangent and heat resistance, the average number of molecular terminal phenolic hydroxyl groups per molecule (the number of terminal hydroxyl groups) is preferably 1 to 5 and more preferably 1.5 to 3.

The number of terminal hydroxyl groups in the polyphenylene ether can be found, for example, from a standard value of a product of the polyphenylene ether. In addition, the number of terminal hydroxyl groups is expressed as, for example, an average value of the number of phenolic hydroxyl groups per molecule of all polyphenylene ethers present in 1 mol of the polyphenylene ether.

The polyphenylene ether may be used alone or in combination of two or more thereof.

Examples of the polyphenylene ether include a polyphenylene ether including 2,6-dimethylphenol and at least one of bifunctional phenol or trifunctional phenol, and poly(2,6-dimethyl-1,4-phenylene oxide). More specifically, the polyphenylene ether is preferably a compound having a structure represented by Formula (PPE).

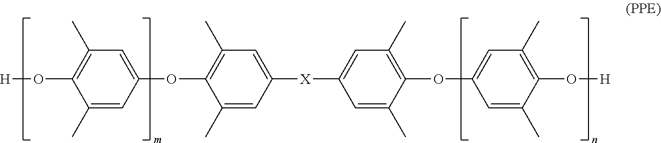

In Formula (PPE), X represents an alkylene group having 1 to 3 carbon atoms or a single bond, m represents an integer of 0 to 20, n represents an integer of 0 to 20, and the sum of m and n represents an integer of 1 to 30.

Examples of the alkylene group in X described above include a dimethylmethylene group.

In a case where heat curing is performed after film formation, from the viewpoint of heat resistance and film-forming property, a weight-average molecular weight (Mw) of the polyphenylene ether is preferably 500 to 5,000 and preferably 500 to 3,000. In addition, in a case where the heat curing is not performed, the weight-average molecular weight (Mw) of the polyphenylene ether is not particularly limited, but is preferably 3,000 to 100,000 and preferably 5,000 to 50,000.

### —Aromatic Polyether Ketone—

The aromatic polyether ketone is not particularly limited, and a known aromatic polyether ketone can be used.

The aromatic polyether ketone is preferably a polyether ether ketone.

The polyether ether ketone is one type of the aromatic polyether ketone, and is a polymer in which bonds are arranged in the order of an ether bond, an ether bond, and a carbonyl bond. It is preferable that the bonds are linked to each other by a divalent aromatic group.

The aromatic polyether ketone may be used alone or in combination of two or more thereof.

Examples of the aromatic polyether ketone include polyether ether ketone (PEEK) having a chemical structure represented by Formula (P1), polyether ketone (PEK) having a chemical structure represented by Formula (P2), polyether ketone ketone (PEKK) having a chemical structure represented by Formula (P3), polyether ether ketone ketone (PEEKK) having a chemical structure represented by Formula (P4), and polyether ketone ether ketone ketone (PEKEKK) having a chemical structure represented by Formula (P5).

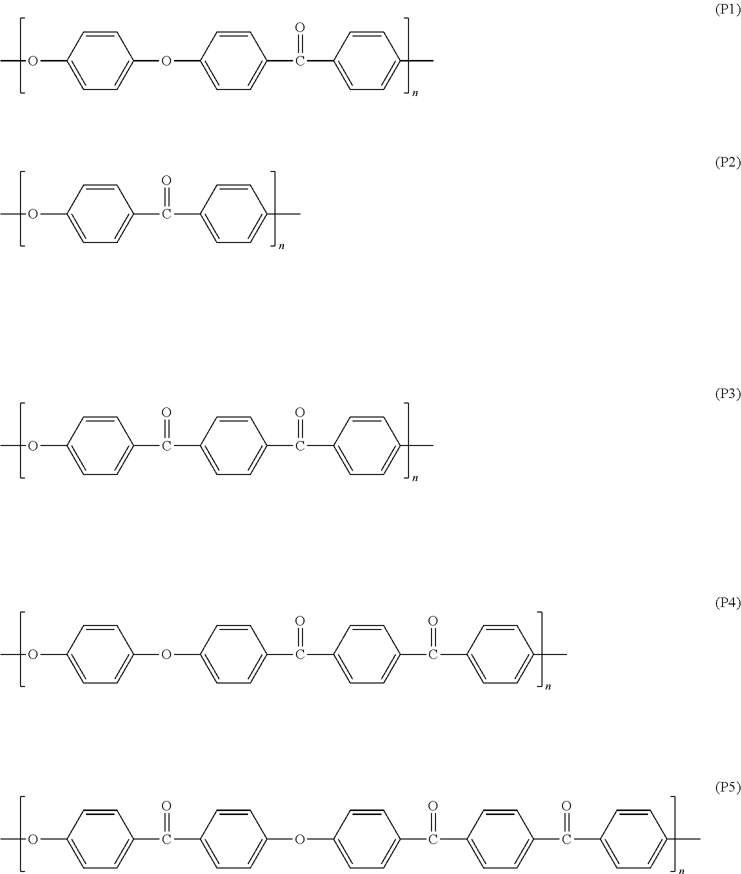

From the viewpoint of mechanical properties, each n of Formulae (P1) to (P5) is preferably 10 or more and more preferably 20 or more. On the other hand, from the viewpoint that the aromatic polyether ketone can be easily produced, n is preferably 5,000 or less and more preferably 1,000 or less. That is, n is preferably 10 to 5,000 and more preferably 20 to 1,000.

The polymer contained in the first resin layer is preferably a polymer soluble in a specific organic solvent (hereinafter, also referred to as “soluble polymer”).

Specifically, the soluble polymer is a polymer in which 0.1 g or more thereof is dissolved at 25° C. in 100 g of at least one solvent selected from the group consisting of N-methylpyrrolidone, N-ethylpyrrolidone, dichloromethane, dichloroethane, chloroform, N,N-dimethylacetamide, γ-butyrolactone, dimethylformamide, ethylene glycol monobutyl ether, and ethylene glycol monoethyl ether.

From the viewpoint of dielectric loss tangent of the film and adhesiveness with a metal, a content of the polymer in the first resin layer is preferably 20% by mass to 99% by mass, more preferably 30% by mass to 98% by mass, still more preferably 40% by mass to 97% by mass, and particularly preferably 50% by mass to 95% by mass with respect to the total mass of the first resin layer.

The first resin layer may contain a filler.

The filler may be particulate or fibrous, and may be an inorganic filler or an organic filler. As the inorganic filler, a known inorganic filler can be used.

Examples of a material of the inorganic filler include boron nitride (BN), aluminum oxide (Al₂O₃), aluminum nitride (AlN), titanium dioxide (TiO₂), silicon dioxide (SiO₂), barium titanate, strontium titanate, aluminum hydroxide, calcium carbonate, and a material containing two or more of these.

Among these, from the viewpoint of reducing the dielectric loss tangent of the film, the inorganic filler preferably includes at least one kind selected from the group consisting of boron nitride, titanium dioxide, and silicon dioxide, and more preferably includes a material (so-called silica particles) containing silicon dioxide.

In addition, the inorganic filler may be hollow particles. As a hollow inorganic filler, hollow particles (glass hollow particles) containing silicon dioxide are preferable. Examples thereof include glass bubbles series (for example, glass bubbles S60HS and the like) manufactured by 3M Japan Limited.

The inorganic filler is preferably silica particles which are solid particles containing silicon dioxide, or glass hollow particles which are hollow particles containing silicon dioxide.

From the viewpoint of thermal expansion coefficient and adhesiveness with a metal, an average particle diameter of the inorganic filler is preferably 5 nm to 40 μm, more preferably 1 μm to 35 μm, still more preferably 5 μm to 35 μm, and particularly preferably 10 μm to 35 μm. In a case where the particles or fibers are flat, the average particle diameter indicates a length in a short side direction.

The average particle diameter of the inorganic filler is a particle diameter (D50) in a case where volume accumulation from a small diameter side is 50% in a volume-based particle size distribution. The D50 is a value measured using a laser diffraction/scattering-type particle size distribution analyzer.

As the organic filler, a known organic filler can be used.

Examples of a material of the organic filler include polyethylene, polystyrene, urea-formalin filler, polyester, cellulose, acrylic resin, fluororesin, cured epoxy resin, crosslinked benzoguanamine resin, crosslinked acrylic resin, a liquid crystal polymer (LCP), and a material containing two or more kinds of these.

Among these, from a viewpoint of reducing the dielectric loss tangent of the film, the organic filler preferably includes at least one selected from the group consisting of a liquid crystal polymer, fluororesin, and polyethylene; more preferably includes at least one kind selected from the group consisting of liquid crystalline polyester, polytetrafluoroethylene, and polyethylene; and still more preferably includes liquid crystalline polyester.

Here, the organic filler (also referred to as liquid crystal polymer particles) containing the liquid crystal polymer can be produced, for example, by polymerizing the liquid crystal polymer and pulverizing the liquid crystal polymer into powder by a pulverizer or the like.

In addition, the organic filler may be fibrous, such as nanofibers, or may be hollow resin particles.

From the viewpoint of thermal expansion coefficient and adhesiveness with a metal, an average particle diameter of the organic filler is preferably 5 nm to 20 μm, more preferably 1 μm to 20 μm, still more preferably 5 μm to 15 μm, and particularly preferably 10 μm to 15 μm.

The average particle diameter of the organic filler is a particle diameter (D50) in a case where volume accumulation from a small diameter side is 50% in a volume-based particle size distribution. The D50 is a value measured using a laser diffraction/scattering-type particle size distribution analyzer.

In a case where the first resin layer contains a filler, a content of the filler is preferably 20% by mass to 80% by mass and more preferably 25% by mass to 75% by mass with respect to the total amount of the first resin layer.

The first resin layer may contain other components in addition to the polymer and the filler, within a range in which the effect of the present disclosure is not significantly impaired.

Known additives can be used as other components. Examples of the other components include a leveling agent, an antifoaming agent, an antioxidant, an ultraviolet absorbing agent, a flame retardant, and a colorant.

The first resin layer may be configured with only one layer or may be configured with two layers or more.

From the viewpoint of improving the strength of the wiring board, an elastic modulus of the first resin layer at 160° C. is preferably 0.5 GPa or more, more preferably 0.8 GPa or more, and still more preferably 1.0 GPa or more. The upper limit value of the above-described elastic modulus is not particularly limited, but is, for example, 10 GPa.

In the present disclosure, the elastic modulus means a storage elastic modulus. The elastic modulus at 160° C. is an elastic modulus which is measured under an environment of 160° C.

The elastic modulus can be controlled by the type of the additive such as a filler, a plasticizer, and a polymer blend, the drying conditions, and the alignment of the resin layer due to stretching or the like.

The elastic modulus is measured by the following method.

The wiring board is cut with a microtome to produce a sample for cross section evaluation. Subsequently, the elastic modulus is measured by observing the sample in a VE-AFM mode using a scanning probe microscope (product name “SPA400”, manufactured by Hitachi High-Tech Science Corporation).

From the viewpoint of strength, dielectric loss tangent, and adhesiveness with a metal layer, a thickness of the first resin layer is preferably 6 μm to 200 μm, more preferably 12 μm to 100 μm, and particularly preferably 20 μm to 60 μm.

### <Wiring Pattern>

The wiring board according to the present disclosure includes wiring patterns arranged on at least one surface of the first resin layer.

A material of the wiring pattern is not particularly limited, but is preferably a metal and more preferably silver or copper.

A thickness of the wiring pattern is not particularly limited, but is preferably 2 μm to 30 μm and more preferably 5 μm to 15 μm.

In regard to the thickness of the wiring pattern, the wiring board is cut with a microtome, and a cross section is observed with an optical microscope. Three or more cross-sectional samples are cut, and a thickness of the wiring pattern in each cross section is measured at three points or more. An average value of the measured values is calculated and adopted as the average thickness.

### <Second Resin Layer>

The wiring board according to the present disclosure includes a second resin layer disposed between the wiring patterns and on the wiring pattern.

The second resin layer contains a resin (that is, a polymer). The type of the polymer contained in the second resin layer is not particularly limited, but from the viewpoint of further reducing the dielectric loss tangent, a preferred aspect of the polymer contained in the second resin layer is the same as the preferred aspect of the polymer contained in the first resin layer.

The second resin layer may be configured with only one layer or may be configured with two layers or more.

In the wiring pattern, from the viewpoint of suppressing distortion of the wiring pattern, an elastic modulus of the second resin layer at 160° C. is preferably less than 1.0 GPa, more preferably 10 MPa or less, and still more preferably 1 MPa or less. The lower limit value of the above-described elastic modulus is not particularly limited, but is, for example, 0.02 MPa.

The elastic modulus is measured by the above-described method.

From the viewpoint of strength, dielectric loss tangent, and adhesiveness with a metal layer, a thickness of the second resin layer is preferably 6 μm to 200 μm, more preferably 12 μm to 100 μm, and particularly preferably 20 μm to 60 μm.

### <Interface Roughnesses Rz1 and Rz2>

In the wiring board according to the present disclosure, in a cross section along a thickness direction, an interface roughness Rz1 of an interface between the first resin layer and the second resin layer is larger than an interface roughness Rz2 of an interface between the first resin layer and the wiring pattern.

Examples of a method of making the interface roughness Rz1 of the interface between the first resin layer and the second resin layer larger than the interface roughness Rz2 of the interface between the first resin layer and the wiring pattern include the following methods.
(1) a method in which, in the formation of the first resin layer, a film containing alkali-soluble particles or acid-soluble particles is used
(2) a method in which, before forming the interface between the first resin layer and the second resin layer, at least one surface of the first resin layer or the second resin layer is roughened
(3) a method in which, in the formation of the first resin layer, a film containing particles having a thermal expansion coefficient larger than that of the polymer contained in the first resin layer or particles having a hygroscopic expansion coefficient smaller than that of the polymer contained in the first resin layer is used

Details of the film containing alkali-soluble particles or acid-soluble particles will be described later.

From the viewpoint of exhibiting adhesion expressed by mechanical bonding between the first resin layer and the second resin layer, the interface roughness Rz1 is preferably 1.0 μm or more, more preferably 1.5 μm or more, and still more preferably 2.0 μm or more. The upper limit value of the interface roughness Rz1 is not particularly limited, but is, for example, 5.0 μm.

From the viewpoint of reducing transmission loss in the wiring pattern, the interface roughness Rz2 is preferably less than 1.0 μm, more preferably 0.8 μm or less, and still more preferably 0.5 μm or less. The lower limit value of the interface roughness Rz2 is not particularly limited, but is, for example, 0.3 μm.

In the present disclosure, the interface roughness is calculated as a maximum height roughness (Rz) which is an interval between a peak line and a valley line by creating an interface shape curve of each layer from an image obtained by cutting out a cross-sectional sample of the wiring board with a microtome and observing the image with an optical microscope. The maximum height roughness is obtained by cutting out five cross sections of the film at any location and obtaining an average value of the calculated maximum height roughness.

### Film

As a first aspect, the film according to the present disclosure contains alkali-soluble particles or acid-soluble particles, and has a dielectric loss tangent of 0.01 or less. Hereinafter, the film according to the first aspect is also referred to as “first film”.

As a second aspect, the film according to the present disclosure contains alkali-soluble particles or acid-soluble particles, and at least one polymer selected from the group consisting of a liquid crystal polymer, a fluororesin, a polymerized substance of a compound which has a cyclic aliphatic hydrocarbon group and a group having an ethylenically unsaturated bond, a polyphenylene ether, and an aromatic polyether ketone. Hereinafter, the film according to the second aspect is also referred to as “second film”.

As a third aspect, the film according to the present disclosure includes a layer A and a layer B provided on at least one surface of the layer A, in which a dielectric loss tangent of the layer A is 0.01 or less, and the layer B contains alkali-soluble particles or acid-soluble particles, and at least one polymer selected from the group consisting of a liquid crystal polymer, a fluororesin, a polymerized substance of a compound which has a cyclic aliphatic hydrocarbon group and a group having an ethylenically unsaturated bond, a polyphenylene ether, and an aromatic polyether ketone. Hereinafter, the film according to the third aspect is also referred to as “third film”.

Contents common to the first film to the third film will be simply described as “film”.

All of the first film, the second film, and the third film contain alkali-soluble particles or acid-soluble particles.

Since both the first film and the second film contain the alkali-soluble particles or the acid-soluble particles, in a case where a metal substrate is etched into a pattern shape after the film is laminated with the metal substrate, the alkali-soluble particles or the acid-soluble particles existing in the vicinity of a film surface at a portion from which the metal substrate is removed are dissolved. By dissolving the alkali-soluble particles or the acid-soluble particles, a part of the film surface at the portion from which the metal substrate has been removed is scraped off, and a surface roughness of the film after the etching treatment is increased.

Since the layer B of the third film contains the alkali-soluble particles or the acid-soluble particles, in a case where a metal substrate is etched into a pattern shape after the film is laminated with the metal substrate on the layer B side, the alkali-soluble particles or the acid-soluble particles existing in the vicinity of a surface of the layer B at a portion from which the metal substrate is removed are dissolved. By dissolving the alkali-soluble particles or the acid-soluble particles, a part of the surface of the film (layer B) at the portion from which the metal substrate has been removed is scraped off, and a surface roughness of the film after the etching treatment is increased.

In a case where the wiring pattern is formed by etching the metal substrate and then the wiring pattern and the resin base material are overlapped with each other to produce the wiring board, since the surface roughness of the film surface at the portion from which the metal substrate has been removed is large, excellent adhesiveness is obtained.

In the present disclosure, “alkali-soluble” means that a solubility in 100 g of a 2.38% by mass tetramethylammonium hydroxide aqueous solution at a liquid temperature of 25° C. is 0.1 g or more.

The alkali-soluble particles may be organic particles or inorganic particles as long as the particles have alkali solubility. Among these, the alkali-soluble particles are preferably organic particles, and more preferably polymer particles. That is, the alkali-soluble particles are more preferably alkali-soluble polymer particles.

The alkali-soluble polymer particles are preferably polymer particles having a functional group such as a phenolic hydroxyl group, a carboxy group, and an ester of these groups in a main chain or a side chain.

Examples of the polymer constituting the alkali-soluble polymer particles include an acrylic resin, a polystyrene resin, a styrene-acrylic copolymer, a polyurethane resin, polyvinyl alcohol, polyvinyl formal, a polyamide resin, a polyester resin, an epoxy resin, a polyacetal resin, a polyhydroxystyrene resin, a polyimide resin, a polybenzoxazole resin, a polysiloxane resin, polyethyleneimine, polyallylamine, and polyalkylene glycol.

In the present disclosure, “acid-soluble” means that a solubility of in 100 g of a 45% by mass second iron chloride aqueous solution at a liquid temperature of 25° C. is 0.1 g or more.

The acid-soluble particles may be organic particles or inorganic particles as long as the particles have acid solubility. Among these, the acid-soluble particles are preferably inorganic particles, and more preferably metal particles. That is, the acid-soluble particles are more preferably acid-soluble metal particles.

Examples of the metal constituting the acid-soluble metal particles include copper, aluminum, and zinc.

From the viewpoint of improving the adhesiveness with a metal, an average particle diameter of the alkali-soluble particles or the acid-soluble particles is preferably 0.5 μm to 5.0 μm, and more preferably 1.0 μm to 3.0 μm.

The average particle diameter or the alkali-soluble particles or the acid-soluble particles is measured using a laser diffraction/scattering-type particle size distribution analyzer. The average particle diameter can be measured by, for example, (product name “Partica LA-960V2”, manufactured by Horiba Ltd.).

In the first film and the second film, from the viewpoint of improving the adhesiveness with a metal, a content of the alkali-soluble particles or the acid-soluble particles is preferably 5% by mass to 75% by mass and more preferably 10% by mass to 50% by mass with respect to the total amount of the film.

In the third film, from the viewpoint of improving the adhesiveness with a metal, a content of the alkali-soluble particles or the acid-soluble particles is preferably 5% by mass to 75% by mass and more preferably 10% by mass to 50% by mass with respect to the total amount of the layer B.

Hereinafter, the configurations of the first film to the third film, other than the alkali-soluble particles or the acid-soluble particles, will be described.

### First Film

The first film contains alkali-soluble particles or acid-soluble particles, and has a dielectric loss tangent of 0.01 or less. The dielectric loss tangent is preferably 0.005 or less and more preferably 0.003 or less. The lower limit value of the dielectric loss tangent is not particularly limited, but is, for example, 0.0005.

A measuring method of the dielectric loss tangent of the first film is as described above.

It is preferable that the first film contains a polymer, and a preferred aspect of the polymer contained in the first film is the same as the preferred aspect of the polymer contained in the first resin layer described above.

In addition, the first film may contain a filler and other components, and details of the filler and other components are the same as those which can be contained in the first resin layer described above.

### Second Film

The second film contains alkali-soluble particles or acid-soluble particles, and at least one polymer selected from the group consisting of a liquid crystal polymer, a fluororesin, a polymerized substance of a compound which has a cyclic aliphatic hydrocarbon group and a group having an ethylenically unsaturated bond, a polyphenylene ether, and an aromatic polyether ketone. Preferred aspects of the polymer contained in the second film are the same as the preferred aspect of the polymer contained in the first resin layer described above.

In addition, the second film may contain a filler and other components, and details of the filler and other components are the same as those which can be contained in the first resin layer described above.

### Third Film

The third film includes the layer A and the layer B provided on at least one surface of the layer A. A dielectric loss tangent of the layer A is preferably 0.01 or less, more preferably 0.005 or less, and still more preferably 0.003 or less. The lower limit value of the dielectric loss tangent is not particularly limited, but is, for example, 0.0005.

A measuring method of the dielectric loss tangent of the layer A is as described above.

It is preferable that the layer A contains a polymer, and a preferred aspect of the polymer contained in the layer A is the same as the preferred aspect of the polymer contained in the first resin layer described above.

In addition, the layer A may contain a filler and other components, and details of the filler and other components are the same as those which can be contained in the first resin layer described above.

From the viewpoint of improving the strength of the third film, the layer A preferably contains a filler. The filler preferably includes at least one selected from the group consisting of a liquid crystal polymer, fluororesin, and polyethylene; more preferably includes at least one kind selected from the group consisting of liquid crystalline polyester, polytetrafluoroethylene, and polyethylene; and still more preferably includes liquid crystalline polyester.

From the viewpoint of adhesiveness with a metal layer, a thickness of the layer A is preferably 5 μm to 90 μm, more preferably 10 μm to 70 μm, and particularly preferably 15 μm to 50 μm.

The layer B contains at least one polymer selected from the group consisting of a liquid crystal polymer, a fluororesin, a polymerized substance of a compound which has a cyclic aliphatic hydrocarbon group and a group having an ethylenically unsaturated bond, a polyphenylene ether, and an aromatic polyether ketone. Preferred aspects of the polymer contained in the layer B are the same as the preferred aspect of the polymer contained in the first resin layer described above.

In addition, the layer B may contain a filler and other components, and details of the filler and other components are the same as those which can be contained in the first resin layer described above.

From the viewpoint of adhesiveness with a metal layer, a thickness of the layer B is preferably 5 μm to 90 μm, more preferably 10 μm to 70 μm, and particularly preferably 15 μm to 50 μm.

The third film may include a layer other than the layer A and the layer B (for example, a layer C), and in a case of including the layer C, it is preferable that the layer C is laminated on the layer A at a side opposite to a side on which the layer B is disposed. From the viewpoint of adhesiveness with a metal, the layer B is preferably the outermost layer.

A manufacturing method of the film according to the present disclosure is not particularly limited, and a known method can be referred to.

Suitable examples of the manufacturing method according to the present disclosure include a casting method, a coating method, and an extrusion method. Among these, a casting method is particularly preferable for forming a relatively thin film, and a co-extrusion method is particularly preferable for forming a thick film. In addition, in a case where the film according to the present disclosure has a multilayer structure, suitable examples thereof include a co-casting method, a multilayer coating method, and a co-extrusion method. Among these, a co-casting method is particularly preferable.

In a case where the multilayer structure in the film is manufactured by the co-casting method or the multilayer coating method, it is preferable that the co-casting method or the multilayer coating method is performed by using a composition for forming the layer A, a composition for forming the layer B, a composition for forming the layer C, or the like obtained by dissolving or dispersing components of each layer in a solvent.

Examples of the solvent include halogenated hydrocarbons such as dichloromethane, chloroform, 1,1-dichloroethane, 1,2-dichloroethane, 1,1,2,2-tetrachloroethane, 1-chlorobutane, chlorobenzene, and o-dichlorobenzene; halogenated phenols such as p-chlorophenol, pentachlorophenol, and pentafluorophenol; ethers such as diethyl ether, tetrahydrofuran, and 1,4-dioxane; ketones such as acetone and cyclohexanone; esters such as ethyl acetate and γ-butyrolactone; carbonates such as ethylene carbonate and propylene carbonate; amines such as triethylamine; nitrogen-containing heterocyclic aromatic compounds such as pyridine; nitriles such as acetonitrile and succinonitrile; amides such as N,N-dimethylformamide, N,N-dimethylacetamide, and N-methylpyrrolidone; urea compounds such as tetramethylurea; nitro compounds such as nitromethane and nitrobenzene; sulfur compounds such as dimethyl sulfoxide and sulfolane; and phosphorus compounds such as hexamethylphosphoramide and tri-n-butyl phosphate.

Among these, the solvent preferably contains an aprotic compound, particularly, an aprotic compound having no halogen atom for low corrosiveness and easiness to handle. A proportion of the aprotic compound to the whole solvent is preferably 50% by mass to 100% by mass, more preferably 70% by mass to 100% by mass, and particularly preferably 90% by mass to 100% by mass. In addition, from the viewpoint of easily dissolving the liquid crystal polymer, as the above-described aprotic compound, an amide such as N,N-dimethylformamide, N,N-dimethylacetamide, tetramethylurea, and N-methylpyrrolidone, or an ester such as γ-butyrolactone is preferable; and N,N-dimethylformamide, N,N-dimethylacetamide, or N-methylpyrrolidone is more preferable.

In addition, in a case where the manufacturing method of the film according to the present disclosure is the co-casting method, the multilayer coating method, the co-extrusion method, or the like described above, a support may be used in the method of manufacturing the film according to the present disclosure.

Examples of the support include a metal drum, a metal band, a glass plate, a resin film, and a metal foil. Among these, the support is preferably a metal drum, a metal band, or a resin film.

Examples of the resin film include a polyimide (PI) film. Examples of commercially available products of the resin film include U-PILEX S and U-PILEX R (manufactured by Ube Corporation), KAPTON (manufactured by Du Pont-Toray Co., Ltd.), and IF30, IF70, and LV300 (manufactured by SKC Kolon PI, Inc.).

In addition, the support may have a surface treatment layer formed on the surface so that the support can be easily peeled off. Hard chrome plating, a fluororesin, or the like can be used as the surface treatment layer.

An average thickness of the support is not particularly limited, but is preferably 25 μm or more and 75 μm or less and more preferably 50 μm or more and 75 μm or less.

In addition, a method for removing at least a part of the solvent from a cast or applied film-like composition (a coating film) is not particularly limited, and a known drying method can be used.

It is preferable that the manufacturing method includes a step of subjecting the film after the formation to a heat treatment (annealing).

From the viewpoint of dielectric loss tangent and peel strength, the heat treatment temperature in the above-described step of heat-treating is preferably 260° C. to 370° C., more preferably 280° C. to 360° C., and still more preferably 300° C. to 350° C. The heat treatment time is preferably 15 minutes to 10 hours and more preferably 30 minutes to 5 hours.

In addition, the manufacturing method of the film according to the present disclosure may include other known steps as necessary.

### Laminate

As a first aspect, the laminate according to the present disclosure includes the first film or the second film, and a metal layer which is disposed on at least one surface of the first film or the second film and has a surface roughness of 1.0 μm or less.

As a second aspect, the laminate according to the present disclosure includes the third film and a metal layer which is disposed on the layer B of the third film and has a surface roughness of 1.0 μm or less.

Examples of the metal contained in the metal layer include copper, silver, gold, and an alloy of these. The metal layer is preferably a copper layer.

As the copper layer, a rolled copper foil formed by a rolling method or an electrolytic copper foil formed by an electrolytic method is preferable.

The laminate may be manufactured by laminating the film and the metal layer.

A method of laminating the film and the metal layer is not particularly limited, and a known laminating method can be used.

In addition, a metal substrate is used as the support in the manufacturing method of the film described above, whereby the laminate can be manufactured without peeling the film from the metal substrate.

A thickness of the metal layer is not particularly limited, but is preferably 3 μm to 30 μm and more preferably 5 μm to 20 μm.

The thickness of the metal layer is calculated by the following method.

The laminate is cut with a microtome, and a cross section is observed with an optical microscope. Three or more cross-sectional samples are cut, and a thickness of a layer to be measured in each cross section is measured at three points or more. An average value of the measured values is calculated and adopted as the average thickness.

The surface roughness of the metal layer is preferably 1.0 μm or less, more preferably 0.8 μm or less, and still more preferably 0.7 μm or less. The lower limit value of the surface roughness is not particularly limited, but is, for example, 0.3 μm.

In a case where the surface roughness of the metal layer is 1.0 μm or less, the transmission loss is suppressed and the dielectric loss tangent is improved.

In the present disclosure, the surface roughness of the metal layer is measured using an optical interference microscope (non-contact surface shape measuring device VertScan, manufactured by Risho System Co., Ltd.).

### Manufacturing Method of Wiring Board

The manufacturing method of a wiring board according to the present disclosure includes a step of etching the metal layer in the above-described laminate to produce a substrate with a wiring pattern, including a first resin substrate and a wiring pattern disposed on at least one surface of the first resin substrate, a step of superimposing a second resin substrate on the wiring pattern of the substrate with a wiring pattern, and a step of heating the substrate with a wiring pattern and the second resin substrate in a state of being superimposed on each other to obtain a wiring board.

### —Manufacturing Step of Substrate With Wiring Pattern—

In the manufacturing method of a wiring board according to the present disclosure, the metal layer in the above-described laminate is etched to produce a substrate with a wiring pattern, including a first resin substrate and a wiring pattern disposed on at least one surface of the first resin substrate.

A method of etching the metal layer in the laminate is not particularly limited, and the etching can be performed by a known method.

The above-described laminate includes the film and the metal layer disposed on at least one surface of the film, and a wiring pattern is obtained by etching the metal layer into a pattern shape.

Since both the first film and the second film contain the alkali-soluble particles or the acid-soluble particles, in a case where the metal layer is etched into a pattern shape, the alkali-soluble particles or the acid-soluble particles existing in the vicinity of a film surface at a portion from which the metal layer is removed are dissolved. By dissolving the alkali-soluble particles or the acid-soluble particles, a part of the film surface at the portion from which the metal layer has been removed is scraped off, and a surface roughness of the film after the etching treatment is increased.

Since both the layer B of the third film contains the alkali-soluble particles or the acid-soluble particles, in a case where the metal layer is etched into a pattern shape, the alkali-soluble particles or the acid-soluble particles existing in the vicinity of a surface of the layer B at a portion from which the metal layer is removed are dissolved. By dissolving the alkali-soluble particles or the acid-soluble particles, a part of the surface of the film (layer B) at the portion from which the metal layer has been removed is scraped off, and a surface roughness of the film after the etching treatment is increased.

The film after the etching treatment corresponds to the first resin substrate in the above-described substrate with a wiring pattern.

The surface roughness of the first resin substrate is adjusted by the size and amount of the alkali-soluble particles or the acid-soluble particles present in the vicinity of the surface of the film.

The above-described laminate includes the film and the metal layer disposed on the film, and the surface roughness of the film is adjusted by the surface roughness of the metal substrate (for example, a metal foil) used for forming the metal layer. It is considered that this is because the film is deformed in conformity with the surface of the metal substrate. Since the interface between the first resin substrate and the wiring pattern corresponds to the interface between the film and the metal layer, the interface roughness Rz2 of the interface between the first resin substrate and the wiring pattern is the same as the surface roughness of the film. On the other hand, the interface roughness Rz1 of the interface between the first resin substrate and the second resin substrate is rougher than the surface roughness of the film based on the surface roughness of the first resin substrate.

Therefore, in the cross section along the thickness direction, the interface roughness Rz1 of the interface between the first resin substrate and the second resin substrate is larger than the interface roughness Rz2 of the interface between the first resin substrate and the wiring pattern.

The first resin substrate is the same as the film, except that at least a part of the alkali-soluble particles or the acid-soluble particles contained in the film is removed by etching.

A preferred aspect of the wiring pattern in the substrate with a wiring pattern is the same as the preferred aspect of the wiring pattern described in the column of the wiring board above.

The substrate with a wiring pattern may have a wiring pattern disposed on only one surface of the first resin substrate, or may have a wiring pattern disposed on both surfaces of the substrate.

### —Superimposition Step—

In the manufacturing method of a wiring board according to the present disclosure, the second resin substrate is superimposed on the wiring pattern of the substrate with a wiring pattern.

In a case where the second resin substrate is superimposed, the second resin substrate may be placed on the wiring pattern, or may be brought into contact with the wiring pattern while being pressed by applying pressure.

The type of the second resin substrate is not particularly limited, but it is preferable to include the film according to the present disclosure.

The second resin substrate may be a substrate including the film according to the present disclosure and an adhesive sheet disposed on one surface of the film. In this case, the adhesiveness is improved by superimposing the adhesive sheet side on the wiring pattern.

In the manufacturing method of a wiring board according to the present disclosure, after the above-described superimposing step, the substrate with a wiring pattern and the second resin substrate are heated in a state of being superimposed on each other to obtain a wiring board.

A heating method is not particularly limited, and the heating can be performed, for example, using a heat pressing machine.

A heating temperature in a case of heating the substrate with a wiring pattern and the second resin substrate in a state of being superimposed on each other is preferably 50° C. to 300° C. and more preferably 100° C. to 250° C.

It is preferable to pressurize in a case of heating the substrate with a wiring pattern and the second resin substrate in a state of being superimposed on each other. The pressure is preferably 0.5 MPa to 30 MPa and more preferably 1 MPa to 20 MPa.

A heating time in a case of heating the substrate with a wiring pattern and the second resin substrate in a state of being superimposed on each other is not particularly limited, but is, for example, 1 minute to 2 hours.

The second resin substrate is preferably the film according to the present disclosure (the first film to the third film). In the step of superimposing the resin substrate, it is preferable that the resin substrate is superimposed such that the second resin layer side is in contact with the substrate with a wiring pattern.

The wiring board according to the present disclosure can be used for various purposes, and can be suitably used in a flexible printed circuit board. Examples

Hereinafter, the present disclosure will be described in more detail using Examples. However, the present disclosure is not limited to the following examples as long as it does not exceed the gist of the present invention.

### Production Example

### <Polymer>

LC-A: liquid crystal polymer produced by production method described below

### —Production of LC-A—

940.9 g (5.0 mol) of 6-hydroxy-2-naphthoic acid, 377.9 g (2.5 mol) of 4-acetaminophen, 415.3 g (2.5 mol) of isophthalic acid, and 867.8 g (8.4 mol) of acetic acid anhydride were added to a reactor provided with a stirrer, a torque meter, a nitrogen gas introduction pipe, a thermometer, and a reflux condenser, the gas inside the reactor was replaced with nitrogen gas, and the mixture was heated from room temperature (23° C.; the same applies hereinafter) to 143° C. over 60 minutes while being stirred in a nitrogen gas stream and was refluxed at 143° C. for 1 hour.

Next, the temperature was raised from 150° C. to 300° C. over 5 hours while distilling off by-produced acetic acid and unreacted acetic acid anhydride, and maintained at 300° C. for 30 minutes. Thereafter, the content was taken out from the reactor and was cooled to room temperature. The obtained solid matter was crushed with a crusher, thereby obtaining powdery liquid crystal polyester A1a.

The liquid crystal polyester Ala was subjected to solid polymerization by increasing the temperature from room temperature to 160° C. over 2 hours and 20 minutes in a nitrogen atmosphere, increasing the temperature from 160° C. to 180° C. over 3 hours and 20 minutes, and maintaining the temperature at 180° C. for 5 hours, and then the resultant was cooled. Next, the resultant was pulverized by a pulverizer to obtain a powdery liquid crystal polyester Alb.

The liquid crystal polyester Alb was subjected to solid polymerization by increasing the temperature from room temperature to 180° C. over 1 hour and 20 minutes in a nitrogen atmosphere, increasing the temperature from 180° C. to 240° C. over 5 hours, and maintaining the temperature at 240° C. for 5 hours, and then the resultant was cooled, thereby obtaining a powdery liquid crystal polyester (LC-A).

LC-B: pellets of a liquid crystal polymer (product name “VECTRA A950”, manufactured by Polyplastics Co., Ltd.)

P-1: cyclic olefin polymer (product name “ARTON F3500”, manufactured by JSR Corporation)

### <Additive>

### Alkali-Soluble Polymer Particles

AS-1: alkali-soluble polymer particles produced by the following production method

40.3 g (0.11 mol) of 2,2-bis(3-amino-4-hydroxyphenyl)-1,1,1,3,3,3-hexafluoropropane and 1500 g of N-methyl-2-pyrrolidone were put into a four-neck separable flask equipped with a thermometer, a stirrer, a raw material charging port, and a nitrogen gas introduction port for dissolution. Thereafter, 35.4 g (0.12 mol) of diphenyl ether-4,4′-dicarboxylic acid dichloride was added dropwise thereto while cooling the reaction system to 0° C. to 5° C.

After the dropwise addition, the temperature of the reaction system was returned to room temperature, and the mixture was stirred for 6 hours. Thereafter, 1.8 g (0.1 mol) of pure water was added thereto, and the mixture was further reacted at 40° C. for 1 hour. After completion of the reaction, the reaction solution was added dropwise to 2000 g of pure water. The sediment was collected by filtration and washed. Vacuum drying was performed to obtain an alkali-soluble polyhydroxyamide (PP-1) which is a polybenzoxazole precursor. A weight-average molecular weight was 32,000 and a number-average molecular weight was 12,500.

17 parts by mass of an epoxy compound (product name “EPICLON 860”, manufactured by DIC Corporation) and 3 parts by mass of a thermal acid generator (product name “WPAG618”, manufactured by FUJIFILM Wako Pure Chemical Corporation) were mixed with 100 parts by mass of the alkali-soluble polyhydroxyamide (PP-1), and γ-butyrolactone was added thereto such that a concentration of the polymer was 30% by mass, thereby obtaining a varnish.

Subsequently, the varnish was cast on a PET support and heated at 110° C. for 3 minutes. A resin film (PM-1) having a film thickness of 80 μm was produced on the PET support.

The resin film (PM-1) was pulverized using a freezer mill (“6770” manufactured by SPEX corporation), and then pulverized using a beads mill (“EASY NANO RMB” manufactured by AIMEX Co., Ltd.) to obtain alkali-soluble polymer particles (AS-1). An average particle diameter of the alkali-soluble polymer particles (AS-1) was 6 μm.
AS-2: alkali-soluble polymer particles (AS-2) were obtained in the same manner as in the alkali-soluble polymer particles (AS-1), except that, in the production method of the alkali-soluble polymer particles (AS-1), the average particle diameter of the polybenzoxazole precursor particles was changed to 4 μm by changing the pulverization conditions for producing the particles; an average particle diameter of the alkali-soluble polymer particles (AS-2) was 4 μm.
AS-3: alkali-soluble polymer particles (AS-3) were obtained by a method in which, in the production method of the alkali-soluble polymer particles (AS-1), the obtained pulverized product (PM-1) was further passed through a mesh having an opening of 8 μm in an ultrasonic vibrating sieve machine; an average particle diameter of the alkali-soluble polymer particles (AS-3) was 4 μm.
AS-4: alkali-soluble polymer particles produced by the following production method

11 parts by mass of an epoxy compound (product name “HP 4700”, manufactured by DIC Corporation) and 3 parts by mass of a thermal acid generator (product name “WPAG618”, manufactured by FUJIFILM Wako Pure Chemical Corporation) were mixed with 100 parts by mass of the above-described alkali-soluble polyhydroxyamide (PP-1), and γ-butyrolactone was added thereto such that a concentration of the polymer was 30% by mass, thereby obtaining a varnish.

Subsequently, the above-described varnish was cast on a PET support and heated at 110° C. for 3 minutes to produce a resin film (PM-4) having a film thickness of 80 μm.

The resin film (PM-4) was pulverized using a freezer mill (“6770” manufactured by SPEX corporation) to obtain alkali-soluble polymer particles (AS-4). An average particle diameter of the alkali-soluble polymer particles (AS-4) was 4 μm.

All of the alkali-soluble polymer particles (AS-1) to (AS-4) had a solubility of 0.1 g or more in 100 g of a 2.38% by mass tetramethylammonium hydroxide aqueous solution at a liquid temperature of 25° C., and were alkali-soluble.

### Acid-Soluble Metal Particles

ME-1: wet copper powder (product name “1300Y”, D50:3.5 μm, manufactured by Mitsui Mining & Smelting Co., Ltd.)

The acid-soluble metal particles (ME-1) had a solubility of 0.1 g or more in 100 g of a 45% by mass second iron chloride aqueous solution at a liquid temperature of 25° C., and were acid-soluble.

### Compound Having Functional Group

M-1: aminophenol-type epoxy resin (product name “jER630LSD”, manufactured by Mitsubishi Chemical Corporation.) was used so that the amount of solid content was the amount shown in Table 1
M-2: thermosetting resin (SLK containing mainly a polymer-type curable compound, manufactured by Shin-Etsu Chemical Co., Ltd.) was used so that the amount of solid content was the amount shown in Table 1

### Filler

F-1: Liquid crystal polymer particles produced by production method described below

1034.99 g (5.5 mol) of 2-hydroxy-6-naphthoic acid, 378.33 g (1.75 mol) of 2,6-naphthalenedicarboxylic acid, 83.07 g (0.5 mol) of terephthalic acid, 272.52 g (2.475 mol; 0.225 mol excess with respect to the total molar amount of 2,6-naphthalenedicarboxylic acid and terephthalic acid) of hydroquinone, 1226.87 g (12 mol) of acetic acid anhydride, and 0.17 g of 1-methylimidazole as a catalyst were added to a reactor provided with a stirrer, a torque meter, a nitrogen gas introduction pipe, a thermometer, and a reflux condenser. After the gas in the reactor was replaced with nitrogen gas, the mixture was heated from room temperature to 145° C. over 15 minutes while being stirred in a nitrogen gas stream and was refluxed at 145° C. for 1 hour.

Next, the mixture was heated from 145° C. to 310° C. over 3 hours 30 minutes while distilling off by-product acetic acid and unreacted acetic acid anhydride and maintained at 310° C. for 3 hours, and a solid liquid crystal polyester (LC-C) was taken out and cooled to room temperature. A flow start temperature of the polyester (LC-C) was 265° C.

Using a jet mill (“KJ-200” manufactured by KURIMOTO Ltd.), the liquid crystal polyester (LC-C) was crushed to obtain liquid crystal polyester particles (F-1). An average particle diameter of the liquid crystal polyester particles (F-1) was 9 μm.
F-2: Copolymer particles of ethylene tetrafluoride and perfluoroalkoxy ethylene (PFA) (melting point: 280° C., average particle diameter: 0.2 μm to 0.5 μm, dielectric loss tangent: 0.001)

### <Film Formation>

Among the film forming methods described below, a method described in Table 1 was selected.

### Co-Casting A (Solution Film Formation)

### —Preparation of Polymer Solution—

The polymer shown in Table 1 and the additive shown in Table 1 were added to N-methylpyrrolidone, and the mixture was stirred at 140° C. for 4 hours in a nitrogen atmosphere, thereby obtaining a polymer solution. The above-described polymer and additive were added at mass ratios shown in Table 1.

Subsequently, first, the polymer solution was allowed to pass through a sintered fiber metal filter having a nominal pore diameter of 10 μm and allowed to pass through a sintered fiber metal filter having the same nominal pore diameter of 10 μm, thereby obtaining each polymer solution for the layer A, the layer B, and the layer C.

In a case where the additive was not dissolved in N-methylpyrrolidone, a liquid crystal polymer solution was prepared without adding the additive, the mixture was allowed to pass through the above-described sintered fiber metal filter, and then the additive was added thereto and stirred at 25° C. for 30 minutes.

### —Production of Copper-Clad Laminated Plate—

Each of the obtained polymer solutions was fed to a casting die equipped with a feedblock adjusted for co-casting, and as a support, a treatment surface of a copper foil (product name “CF-T9DA-SV-18”, manufactured by FUKUDA METAL FOIL & POWDER CO., LTD., thickness: 18 μm, surface roughness Rz of a bonding surface (treatment surface): 0.85 μm) was cast so that the layer B side was in contact with the copper foil, thereby producing a laminate of layer C/layer A/layer B/copper layer. The laminate was dried at 40° C. for 4 hours to remove the solvent from the casting film, and then heat-treated in a nitrogen atmosphere at a temperature rising from room temperature (25° C.) to 270° C. at 1° C./min and maintained at this temperature for 2 hours. In this manner, a laminate (copper-clad laminated plate) including the film (layer C/layer A/layer B) and the copper layer was obtained.

### Co-Casting B (Solution Film Formation)

### —Preparation of Polymer Solution—

The polymer shown in Table 1 was added to dichloromethane, and the mixture was stirred at 60° C. for 30 minutes to form a solution, and allowed to pass through a sintered fiber metal filter having a nominal pore diameter of 10 μm first and allowed to pass through a sintered fiber metal filter having the same nominal pore diameter of 10 μm again. Subsequently, the additive shown in Table 1 was added so as to have the mass ratio shown in Table 1, and the mixture was stirred at 25° C. for 30 minutes to obtain a polymer solution.

### —Production of Copper-Clad Laminated Plate—

Each of the obtained polymer solutions was fed to a casting die equipped with a multimanifold for adjustment to co-casting in a three-layer configuration (layer C/layer A/layer B), and a treatment surface of a copper foil (product name “CF-T9DA-SV-18”, manufactured by FUKUDA METAL FOIL & POWDER CO., LTD., thickness: 18 μm, surface roughness Rz of a bonding surface (treatment surface): 0.85 μm) was cast so that the layer B side was in contact with the copper foil, thereby producing a laminate of layer C/layer A/layer B/copper foil. The laminate was dried at 100° C. for 3 minutes and then dried at 170° C. for 3 minutes to remove the solvent from the casting film. In this manner, a laminate (copper-clad laminated plate) including the film (layer C/layer A/layer B) and the copper layer was obtained.

### Multilayer Coating

### —Preparation of Polymer Solution—

The polymer shown in Table 1 and the additive shown in Table 1 were added to N-methylpyrrolidone, and the mixture was stirred at 140° C. for 4 hours in a nitrogen atmosphere, thereby obtaining a polymer solution. The above-described polymer and additive were added at mass ratios shown in Table 1.

Subsequently, first, the polymer solution was allowed to pass through a sintered fiber metal filter having a nominal pore diameter of 5 μm and allowed to pass through a sintered fiber metal filter having the same nominal pore diameter of 5 μm, thereby obtaining each polymer solution for the layer A, the layer B, and the layer C.

### —Production of Copper-Clad Laminated Plate—

The obtained polymer solutions for the layer A, the layer B, and the layer C were fed to a slot die coater equipped with a slide coater, and applied onto a treatment surface of a copper foil (product name “CF-T9DA-SV-18”, manufactured by FUKUDA METAL FOIL & POWDER CO., LTD., thickness: 18 μm, surface roughness Rz of a bonding surface (treatment surface): 0.85 μm) to product a laminate of layer C/layer A/layer B/copper layer. The laminate was dried at 40° C. for 4 hours to remove the solvent from the coating film, and then heat-treated in a nitrogen atmosphere at a temperature rising from room temperature to 270° C. at 1° C./min and maintained at this temperature for 2 hours. In this manner, a laminate (copper-clad laminated plate) including the film (layer C/layer A/layer B) and the copper layer was obtained.

### Co-Extrusion (Melt Film Formation)

### —Production of Resin Pellets—

The polymer and additive shown in Table 1 were mixed with each other, and the mixture was pelletized in a nitrogen atmosphere using a biaxial extruder. The obtained pellets for the layer A were dried with dry air at 80° C. and used.

### —Production of Film—

The obtained pellets were supplied into a cylinder through the same supply port of the biaxial extruder having a screw diameter of 50 mm, and heated and kneaded at 340° C. to 350° C. to obtain a kneaded material. Subsequently, the kneaded material for the layer A was fed to a T-die having a multi-manifold structure, and a film-like kneaded material in a molten state was discharged and solidified on a chill roll. The obtained film was peeled off from the chill roll and tenter-stretched to adjust anisotropy of elastic modulus (MD/TD) to be 2 or less.

Furthermore, the polymer solution for the layer B and the polymer solution for the layer C were applied to one corona-treated surface of the layer A (layer B) and the other surface (layer C) with a die coater, dried at 40° C. for 4 hours, and then dried at 120° C. for 3 hours to remove the solvent from the coating film and obtain a film.

### —Production of Copper-Clad Laminated Plate—

A copper foil (product name “CF-T9DA-SV-18”, manufactured by FUKUDA METAL FOIL & POWDER CO., LTD., thickness: 18 μm, surface roughness Rz of a bonding surface (treatment surface): 0.85 μm) was placed on the surface of the obtained polymer film such that the treatment surface of the copper foil was in contact with the surface on the layer B side, and using a laminator (“Vacuum laminator V-130” manufactured by Nikko-Materials Co., Ltd.), lamination was performed for 1 minute under conditions of 140° C. and a laminating pressure of 0.4 MPa, thereby obtaining a single-sided copper foil laminated plate precursor.

Furthermore, the obtained precursor was heat-treated by raising a temperature from room temperature to 270° C. at 1° C./min in a nitrogen atmosphere and maintaining this temperature for 2 hours. In this manner, a laminate (copper-clad laminated plate) including the film (layer C/layer A/layer B) and the copper layer was obtained.

### Production of Flexible Wiring Board

Using the above-described copper-clad laminated plate, a flexible wiring board having a four-layer stripline structure of an outer layer plane (ground layer) was produced.

### (Step of Forming Substrate With Wiring Pattern)

The copper layer of the above-described copper-clad laminated plate (layer C/layer A/layer B/copper layer) was patterned by a known photo-fabrication method to produce a substrate with a wiring pattern [first resin substrate (layer C/layer A/layer B′)/wiring pattern] including three pairs of signal lines. A length of the signal line was 100 mm, and a width of the signal line was set such that characteristic impedance was 50Ω.

In Examples 1 to 13, a ferric chloride aqueous solution was used as an etchant. A part of the copper layer was etched into a pattern shape and removed, and then the copper layer was washed with a potassium hydroxide aqueous solution and pure water. After the washing, the copper-clad laminated plate was dried. After the patterning treatment of the copper layer, a part of the alkali-soluble polymer particles contained in the layer B was removed. In Examples 1 to 13, the “layer B′” means a layer B from which a part of the alkali-soluble polymer particles had been removed.

In Example 14, a ferric chloride aqueous solution was used as an etchant. A part of the copper layer was etched into a pattern shape and removed, and then the copper layer was washed with pure water. After the washing, the copper-clad laminated plate was dried. After the patterning treatment of the copper layer, a part of the acid-soluble metal particles contained in the layer B was removed. In Example 14, the “layer B′” means a layer B from which a part of the acid-soluble metal particles had been removed.

### (Lamination Step)

The above-described substrate with a wiring pattern, the above-described copper-clad laminated plate, and an adhesive sheet (“NIKAFLEX SAFY” manufactured by NIKKAN INDUSTRIAL CO., LTD., thickness: 25 μm) were used. The above-described substrate with a wiring pattern and the above-described copper-clad laminated plate were adhered to each other through the adhesive sheet such that the film (that is, the layer C) side of the copper-clad laminated plate faced the surface of the substrate with a wiring pattern, having the wiring pattern. That is, the second resin substrate ([adhesive sheet/film (layer C/layer A/layer B)]/copper layer) was superimposed on the wiring pattern of the substrate with a wiring pattern. A flexible wiring board was produced by performing heat pressing at 160° C. under a pressure of 4 MPa for 40 minutes. The flexible wiring board included substrate with a wiring pattern/adhesive sheet/layer C/layer A/layer B/copper layer laminated in this order, and wiring patterns disposed on at least one surface of the first resin layer (layer C/layer A/layer B′), and a second resin layer (layer derived from the adhesive sheet/layer C/layer A/layer B) disposed between the wiring patterns and on the wiring pattern.

In the wiring pattern, the elastic modulus of the second resin layer at 160° C. was 2 MPa.

Using the produced flexible wiring board, an interface roughness Rz1 of an interface between the first resin layer and the second resin layer and an interface roughness Rz2 of an interface between the first resin layer and the wiring pattern were measured.

In addition, using the produced flexible wiring board, a dielectric loss tangent of the first resin layer, an elastic modulus of the first resin layer at 160° C., and a peel strength were measured.

The dielectric loss tangent of the film (layer C/layer A/layer B) and the dielectric loss tangent of the first resin layer (layer C/layer A/layer B′) were equivalent to each other, and the difference therebetween was 0.001 or less.

The measuring methods were as follows. The measurement results are shown in Table 1.

### Interface Roughnesses Rz1 and Rz2

A cross-sectional sample of the flexible wiring board parallel to a normal direction of the substrate surface was cut out with a microtome, and an interface shape curve of each layer was created, and the interface roughnesses Rz1 and Rz2 were calculated as an interval between a peak line and a valley line.

### Dielectric Loss Tangent

A cross-sectional sample of the first resin layer was cut out from the flexible wiring board.

The dielectric loss tangent was measured by a resonance perturbation method at a frequency of 10 GHz. A 10 GHz cavity resonator (CP531 manufactured by Kanto Electronics Application & Development Inc.) was connected to a network analyzer (“E8363B” manufactured by Agilent Technology), a sample (width: 2 mm×length: 80 mm) was inserted into the cavity resonator, and the dielectric loss tangent of the first resin layer was measured based on a change in resonance frequency for 96 hours before and after the insertion in an environment of a temperature of 25° C. and a humidity of 60% RH.

### Peel Strength

A test piece for peeling, having a width of 10 mm, was produced from the flexible wiring board. The first resin layer side was fixed to a flat plate with double-sided adhesive tape, and a strength (kN/m) in a case of peeling the second resin layer from the first resin layer was measured at a temperature of 25° C. and a rate of 50 mm/min according to 180° method of JIS C 5016 (1994).

TABLE 1

| | Layer B (surface layer) | | | | | | | Layer A ( [symbol] layer) | | | | | Layer C (surface layer) | |
|---|---|---|---|---|---|---|---|---|---|---|---|---|---|---|
| | Polymer | | Additive 1 | | Additive 2 | | | Polymer | | Additive 1 | | | Polymer | |
| | | Content | | Content | | Content | | | Content | | Content | | | Content |
| | | [part by | | [part by | | [part by | Thickness | | [part by | | [part by | Thickness | | [part by |
| | Type | mass] | Type | mass] | Type | mass] | [μm] | Type | mass] | Type | mass] | [μm] | Type | mass] |
| Example 1 | LC-A | 75 | M-1 | 5 | AS-1 | 20 | 5 | LC-A | 50 | F-1 | 50 | 42 | LC-A | 75 |
| Example 2 | LC-A | 75 | M-1 | 5 | AS-2 | 20 | 5 | LC-A | 50 | F-1 | 50 | 42 | LC-A | 75 |
| Example 3 | LC-A | 75 | M-1 | 5 | AS-3 | 10 | 5 | LC-A | 50 | F-1 | 50 | 42 | LC-A | 75 |
| Example 4 | LC-A | 75 | M-1 | 5 | AS-3 | 20 | 5 | LC-A | 50 | F-1 | 50 | 42 | LC-A | 75 |
| Example 5 | LC-A | 75 | M-1 | 5 | AS-3 | 20 | 8 | LC-A | 50 | F-1 | 50 | 37 | LC-A | 75 |
| Example 6 | LC-A | 75 | M-1 | 5 | AS-3 | 20 | 5 | LC-A | 25 | F-1 | 75 | 42 | LC-A | 75 |
| Example 7 | LC-A | 75 | M-1 | 5 | AS-3 | 20 | 5 | LC-A | 25 | F-1 | 75 | 42 | LC-A | 75 |
| Example 8 | LC-A | 75 | M-1 | 5 | AS-3 | 20 | 5 | LC-A | 25 | F-1 | 75 | 42 | LC-A | 75 |
| Example 9 | LC-A | 75 | M-1 | 5 | AS-4 | 20 | 5 | LC-A | 50 | F-1 | 50 | 42 | LC-A | 75 |
| Example 10 | LC-A | 75 | M-2 | 5 | AS-3 | 20 | 5 | LC-A | 50 | F-1 | 50 | 42 | LC-A | 75 |
| Example 11 | LC-A | 75 | M-1 | 5 | AS-3 | 20 | 5 | LC-A | 25 | F-2 | 75 | 42 | LC-A | 75 |
| Example 12 | LC-B | 75 | M-1 | 5 | AS-3 | 20 | 5 | LC-B | 100 | — | 0 | 42 | LC-B | 75 |
| Example 13 | P-1 | 75 | M-1 | 5 | AS-3 | 20 | 5 | P-1 | 100 | — | 0 | 42 | P-3 | 75 |
| Example 14 | LC-A | 75 | M-1 | 5 | ME-1 | 20 | 5 | LC-A | 50 | F-1 | 50 | 42 | LC-A | 75 |
| Comparative | LC-A | 100 | M-1 | 5 | — | — | 5 | LC-A | 100 | — | 0 | 42 | LC-A | 100 |
| Example 1 | | | | | | | | | | | | | | |

| | Layer C (surface layer) | | | | | | Evaluation result | | | | |
|---|---|---|---|---|---|---|---|---|---|---|---|
| | Additive 1 | | Additive 2 | | | | | Elastic | [symbol] | | |
| | | Content | | Content | | | [symbol] | [symbol] | roughness | | Peel |
| | | [part by | | [part by | Thickness | Film | [symbol] | at 160° C. | [symbol] | [symbol] | strength |
| | Type | mass] | Type | mass] | [μm] | formation | [symbol] | [GPa] | [μm] | [μm] | [kN/m] |
| Example 1 | M-1 | 5 | — | — | 3 | C [symbol] | 0.002 | 0.8 | 3.5 | 0.7 | 1.3 |
| | | | | | | A | | | | | |
| Example 2 | M-1 | 5 | — | — | 3 | C [symbol] | 0.002 | 0.8 | 3.0 | 0.7 | 1.2 |
| | | | | | | A | | | | | |
| Example 3 | M-1 | 5 | — | — | 3 | C [symbol] | 0.002 | 0.8 | 3.5 | 0.7 | 1.0 |
| | | | | | | A | | | | | |
| Example 4 | M-1 | 5 | — | — | 3 | C [symbol] | 0.002 | 0.8 | 2.5 | 0.7 | 1.1 |
| | | | | | | A | | | | | |
| Example 5 | M-1 | 5 | — | — | 5 | C [symbol] | 0.003 | 0.8 | 4.0 | 0.7 | 1.3 |
| | | | | | | A | | | | | |
| Example 6 | M-1 | 5 | — | — | 3 | C [symbol] | 0.002 | 0.8 | 2.7 | 0.7 | 1.2 |
| | | | | | | A | | | | | |
| Example 7 | M-1 | 5 | — | — | 3 | Multilayer | 0.002 | 0.8 | 2.7 | 0.7 | 1.2 |
| | | | | | | [symbol] | | | | | |
| Example 8 | M-1 | 5 | AS-3 | 2 [symbol] | 3 | C [symbol] | 0.002 | 0.8 | 2.7 | 0.7 | 1.2 |
| | | | | | | A | | | | | |
| Example 9 | M-1 | 5 | — | — | 3 | C [symbol] | 0.002 | 0.8 | 2.5 | 0.7 | 1.1 |
| | | | | | | A | | | | | |
| Example 10 | M-2 | 5 | — | — | 3 | C [symbol] | 0.002 | 0.8 | 2.5 | 0.7 | 1.1 |
| | | | | | | A | | | | | |
| Example 11 | M-1 | 5 | — | — | 3 | C [symbol] | 0.001 | 0.6 | 2.7 | 0.7 | 1.0 |
| | | | | | | A | | | | | |
| Example 12 | M-1 | 5 | — | — | 3 | C [symbol] | 0.002 | 0.9 | 2.5 | 0.7 | 0.8 |
| | | | | | | [symbol] | | | | | |
| Example 13 | M-1 | 5 | — | — | 3 | C [symbol] | 0.002 | 0.9 | 2.5 | 0.7 | 1.1 |
| | | | | | | B | | | | | |
| Example 14 | M-1 | 5 | — | — | 3 | C [symbol] | 0.002 | 0.9 | 2.3 | 0.7 | 1.0 |
| | | | | | | A | | | | | |
| Comparative | M-1 | 5 | — | — | 3 | C [symbol] | 0.002 | 0.9 | 0.7 | 0.7 | 0.1 |
| Example 1 | | | | | | A | | | | | |

[symbol]

indicates data missing or illegible when filed

As shown in Table 1, in Examples 1 to 14, it was found that, since the wiring board included the first resin layer, the wiring patterns arranged on at least one surface of the first resin layer, and the second resin layer disposed between the wiring patterns and on the wiring patterns, and in the cross section along the thickness direction, the interface roughness Rz1 of the interface between the first resin layer and the second resin layer was larger than the interface roughness Rz2 of the interface between the first resin layer and the wiring pattern, the adhesiveness was excellent.

On the other hand, in Comparative Example 1, it was found that the adhesiveness was deteriorated because the interface roughness Rz1 of the interface between the first resin layer and the second resin layer was the same as the interface roughness Rz2 of the interface between the first resin layer and the wiring pattern.

The disclosure of Japanese Patent Application No. 2022-013504 filed on Jan. 31, 2022 is incorporated in the present specification by reference. In addition, all documents, patent applications, and technical standards described in the present specification are incorporated herein by reference to the same extent as in a case of being specifically and individually noted that individual documents, patent applications, and technical standards are incorporated by reference.

What is claimed is:

1. A wiring board, comprising:
a first resin layer;
wiring patterns arranged on at least one surface of the first resin layer; and
a second resin layer disposed between the wiring patterns and on the wiring patterns,
wherein, in a cross section along a thickness direction, an interface roughness Rz1 of an interface between the first resin layer and the second resin layer is larger than an interface roughness Rz2 of an interface between the first resin layer and the wiring pattern.

2. The wiring board according to claim 1,
wherein the interface roughness Rz2 is less than 1.0 μm.

3. The wiring board according to claim 1,
wherein the interface roughness Rz1 is 1.0 μm or more.

4. The wiring board according to claim 1,
wherein an elastic modulus of the second resin layer between the wiring patterns at 160° C. is less than 1.0 GPa.

5. The wiring board according to claim 1,
wherein a thickness of the wiring pattern is 2 μm to 30 μm.

6. The wiring board according to claim 1,
wherein a dielectric loss tangent of the first resin layer is 0.01 or less.

7. The wiring board according to claim 1,
wherein the first resin layer comprises at least one polymer selected from the group consisting of a liquid crystal polymer, a fluororesin, a polymerized substance of a compound which has a cyclic aliphatic hydrocarbon group and a group having an ethylenically unsaturated bond, a polyphenylene ether, and an aromatic polyether ketone.

8. The wiring board according to claim 1,
wherein an elastic modulus of the first resin layer at 160° C. is 0.5 GPa or more.

9. A film, comprising alkali-soluble particles or acid-soluble particles.

10. The film according to claim 9,
wherein a dielectric loss tangent is 0.01 or less.

11. The film according to claim 9, further comprising:
at least one polymer selected from the group consisting of a liquid crystal polymer, a fluororesin, a polymerized substance of a compound which has a cyclic aliphatic hydrocarbon group and a group having an ethylenically unsaturated bond, a polyphenylene ether, and an aromatic polyether ketone.

12. The film according to claim 9, comprising:
a layer A; and
a layer B provided on at least one surface of the layer A,
wherein a dielectric loss tangent of the layer A is 0.01 or less, and
the layer B comprises the alkali-soluble particles or the acid-soluble particles, and at least one polymer selected from the group consisting of a liquid crystal polymer, a fluororesin, a polymerized substance of a compound which has a cyclic aliphatic hydrocarbon group and a group having an ethylenically unsaturated bond, a polyphenylene ether, and an aromatic polyether ketone.

13. A laminate, comprising:
the film according to claim 10; and
a metal layer which is disposed on at least one surface of the film and has a surface roughness of 1.0 μm or less.

14. A laminate, comprising:
the film according to claim 11; and
a metal layer which is disposed on at least one surface of the film and has a surface roughness of 1.0 μm or less.

15. A laminate, comprising:
the film according to claim 12; and
a metal layer which is disposed on the layer B of the film and has a surface roughness of

1. 0 μm or less.

16. A manufacturing method of a wiring board, comprising:
etching the metal layer in the laminate according to claim 13 to produce a substrate with a wiring pattern, including a first resin substrate and a wiring pattern disposed on at least one surface of the first resin substrate;
superimposing a second resin substrate on the wiring pattern of the substrate with a wiring pattern; and
heating the substrate with a wiring pattern and the second resin substrate in a state of being superimposed on each other to obtain a wiring board,
wherein, in a cross section along a thickness direction, an interface roughness Rz1 of an interface between the first resin substrate and the second resin substrate is larger than an interface roughness Rz2 of an interface between the first resin substrate and the wiring pattern.

17. A manufacturing method of a wiring board, comprising:
etching the metal layer in the laminate according to claim 14 to produce a substrate with a wiring pattern, including a first resin substrate and a wiring pattern disposed on at least one surface of the first resin substrate;
superimposing a second resin substrate on the wiring pattern of the substrate with a wiring pattern; and
heating the substrate with a wiring pattern and the second resin substrate in a state of being superimposed on each other to obtain a wiring board,
wherein, in a cross section along a thickness direction, an interface roughness Rz1 of an interface between the first resin substrate and the second resin substrate is larger than an interface roughness Rz2 of an interface between the first resin substrate and the wiring pattern.

18. A manufacturing method of a wiring board, comprising:
etching the metal layer in the laminate according to claim 15 to produce a substrate with a wiring pattern, including a first resin substrate and a wiring pattern disposed on at least one surface of the first resin substrate;
superimposing a second resin substrate on the wiring pattern of the substrate with a wiring pattern; and
heating the substrate with a wiring pattern and the second resin substrate in a state of being superimposed on each other to obtain a wiring board,
wherein, in a cross section along a thickness direction, an interface roughness Rz1 of an interface between the first resin substrate and the second resin substrate is larger than an interface roughness Rz2 of an interface between the first resin substrate and the wiring pattern.
